(19) United States
(12) Patent Application Publication
(10) Pub. No.: US 2018/0115156 A1
(43) Pub. Date: Apr. 26, 2018

(54) SEMICONDUCTOR INTEGRATED CIRCUIT AND SEMICONDUCTOR DEVICE INCLUDING THE SAME

(71) Applicant: Renesas Electronics Corporation, Tokyo (JP)

(72) Inventor: Koki NARITA, Tokyo (JP)

(21) Appl. No.: 15/674,692

(22) Filed: Aug. 11, 2017

(30) Foreign Application Priority Data
Oct. 20, 2016 (JP) 2016-205890

(51) Int. Cl. H02H 9/04; H03K 5/08; H01L 27/02

(52) U.S. Cl. CPC H02H 9/046; H01L 27/0296; H03K 5/08

(57) ABSTRACT

According to an embodiment, a semiconductor integrated circuit includes a circuit block provided between a power source voltage line and a reference voltage line, a circuit block provided between a power source voltage line and a reference voltage line, a clamp unit which is provided between the power source voltage line and the reference voltage line and is conductive when it is detected that an ESD voltage is applied using a first time constant, a trigger circuit which causes a trigger signal to be active when it is detected that an ESD voltage is applied using a second time constant smaller than the first time constant, and a transistor which is provided between a signal line, between the circuit blocks, and the power source voltage line or the reference voltage line.

### CROSS-REFERENCE TO RELATED APPLICATIONS

The disclosure of Japanese Patent Application No. 2016-205890 filed on Oct. 20, 2016 including the specification, drawings and abstract is incorporated herein by reference in its entirety.

The present invention relates to a semiconductor integrated circuit and a semiconductor device including the same, and relates, for example, to a semiconductor integrated circuit suitable for preventing breakdown of a transistor due to generation of electrostatic discharge and a semiconductor device including the same.

### BACKGROUND

In a semiconductor device, provided is an ESD (Electro Static Discharge) protective circuit for preventing electrostatic discharge. The discharge models of the ESD includes an HBM (Human Body Model), an MM (Machine Model), and a CDM (Charged Device Model). The HBM is a model of electrostatic discharge generated by discharging electric charges charged to a human body to the semiconductor device. The MM is a model of electrostatic discharge generated by discharging electric charges charged to a metal-made unit with a larger capacity and lower resistance than the human body to the semiconductor device. The CDM is a model of electrostatic discharge generated by discharging electric charges charged to the package of the semiconductor device through an external terminal.

In recent years, by subdivision of the process, the gate withstand voltage of the MOS transistor is decreased. Thus, when electrostatic discharge of the CDM is generated, a high voltage may possibly be applied to the gate of the MOS transistor which receives a signal transmitted between circuits driven by different power sources. In this case, a problem is that the gate of this MOS transistor is broken down.

Japanese Unexamined Patent Application Publication No. 2006-100606 discloses a solution to this problem. The semiconductor device disclosed in Japanese Unexamined Patent Application Publication No. 2006-100606 includes a first circuit block, a second circuit block, a first clamp circuit, a second clamp circuit, and a third clamp circuit. The first circuit block is operated by a first power source voltage and a first reference voltage. The second circuit block is operated by a second power source voltage and a second reference voltage. The first clamp circuit clamps between the first power source voltage and the second reference voltage. The second clamp circuit clamps between the second power source voltage and the first reference voltage. The third clamp circuit clamps between the first reference voltage and the second reference voltage. With this configuration, the semiconductor device can prevent the breakdown due to, particularly, electrostatic discharge of the CDM, of electrostatic discharges generated between a plurality of power source systems.

### SUMMARY

In the configuration of Japanese Unexamined Patent Application Publication No. 2006-100606, when a gate withstand voltage of the MOS transistor is decreased due to the subdivision of the process, it is necessary to decrease a gate voltage of the MOS transistor which receives a signal transmitted between circuit blocks driven by different power sources, by increasing the size of the first to third clamp circuits to improve the performance. Thus, the configuration of Japanese Unexamined Patent Application Publication No. 2006-100606 has a problem of increasing the circuit scale. Other objects and new features will be apparent from the descriptions of the present specification and the accompanying drawings.

According to an embodiment, a semiconductor device includes a first circuit block which is provided between a first power source voltage line and a first reference voltage line, a second circuit block which is provided between a second power source voltage line and a second reference voltage line, a clamp unit which is provided between the first power source voltage line and the second reference voltage line, and is conductive when it is detected that an ESD voltage is applied between the first power source voltage line and the second reference voltage line using a first time constant, a trigger circuit which is provided between the first power source voltage line and the second reference voltage line, and causes a trigger signal to be active when it is detected that an ESD voltage is applied between the first power source voltage line and the second reference voltage line using a second time constant smaller than the first time constant, and a switch which is provided between a signal line between the first and second circuit blocks and one of the first power source voltage line and the second reference voltage line, and is ON when the trigger signal is active.

According to another embodiment, a semiconductor device includes a regulator which generates a predetermined internal voltage from a first power source voltage supplied to a first power source voltage line, a first circuit block which is provided between an internal voltage line to which the internal voltage is supplied and a first reference voltage line, a second circuit block which is provided between a second power source voltage line and a second reference voltage line, a clamp unit which is provided between the first power source voltage line and the second reference voltage line, and is conductive when it is detected that an ESD voltage is applied between the first power source voltage line and the second reference voltage line using a first time constant, a trigger circuit which is provided between the first power source voltage line and the second reference voltage line, and causes a trigger signal to be active, when it is detected that an ESD voltage is applied between the first power source voltage line and the second reference voltage line using a second time constant smaller than the first time constant, and a switch which is provided between the internal voltage line and the second reference voltage line, and is ON when the trigger signal is active.

According to the embodiment, it is possible to provide a semiconductor integrated circuit capable of preventing breakdown of a transistor due to generation of electrostatic discharge and a semiconductor device including the circuit, without increasing the circuit scale.

### BRIEF DESCRIPTION OF THE DRAWINGS

FIG. 1 is a block diagram illustrating a configuration example of a semiconductor integrated circuit according to an embodiment 1.

FIG. 2 is a diagram illustrating an example of a layout configuration of a semiconductor device on which the semiconductor integrated circuit illustrated in FIG. 1 is mounted.

FIG. 3 is a diagram illustrating an enlarged view of the periphery of an analog IP region, of the layout configuration of the semiconductor device illustrated in FIG. 2.

FIG. 4 is a diagram for explaining an ESD protective operation by a semiconductor integrated circuit before a secondary clamp circuit is adopted.

FIG. 5 is a diagram for explaining the ESD protective operation by the semiconductor integrated circuit, illustrated in FIG. 1, in which the secondary clamp circuit is adopted.

FIG. 6 is a diagram illustrating a specific configuration example of a clamp circuit 13 illustrated in FIG. 1.

FIG. 7 is a diagram illustrating a specific configuration example of a clamp circuit 14 illustrated in FIG. 1.

FIG. 8 is a diagram illustrating a first specific configuration example of a trigger circuit illustrated in FIG. 1.

FIG. 9 is a diagram illustrating a second specific configuration example of the trigger circuit illustrated in FIG. 1.

FIG. 10 is a block diagram illustrating a modification of the semiconductor integrated circuit illustrated in FIG. 1.

FIG. 11 is a block diagram illustrating a configuration example of a semiconductor integrated circuit according to an embodiment 2.

FIG. 12 is a block diagram illustrating a modification of the semiconductor integrated circuit illustrated in FIG. 11.

FIG. 13 is a block diagram illustrating a configuration example of a semiconductor integrated circuit according to an embodiment 3.

### DETAILED DESCRIPTION

Descriptions will now be made to preferred embodiments with reference to the accompanying drawings. The drawings are simplified, and thus the technical range of the preferred embodiments should not narrowly be interpreted based on the accompanying drawings. The same constituent elements are identified by the same reference symbols, and thus will not be described over and over.

In the following preferred embodiments, if necessary for convenience sake, descriptions will be made to divided plural sections or preferred embodiments, however, unless otherwise specified, they are not mutually irrelevant, but one is in relations of modifications, application examples, details, supplementary explanations of apart or whole of the other. Further, in the following preferred embodiments, in the case of reference to the number of an element (including its quantity, numeric value, amount, range), unless otherwise specified and unless clearly limited in principle, the present invention is not limited to the specified number, and a number over or below the specified one may be used.

In the following preferred embodiments, the constituent elements (including the operation steps) are not necessarily indispensable, unless otherwise specified and unless considered that they are obviously required in principle. Similarly, in the following preferred embodiments, in the reference of the forms of the constituent elements or the positional relationships, they intend to include those approximating or similar substantially to the forms and like, unless otherwise specified and unless considered that they are obviously not required in principle. This is also true of the foregoing numerical values (including its quantity, numeric value, amount, range) and the range.

### Embodiment 1

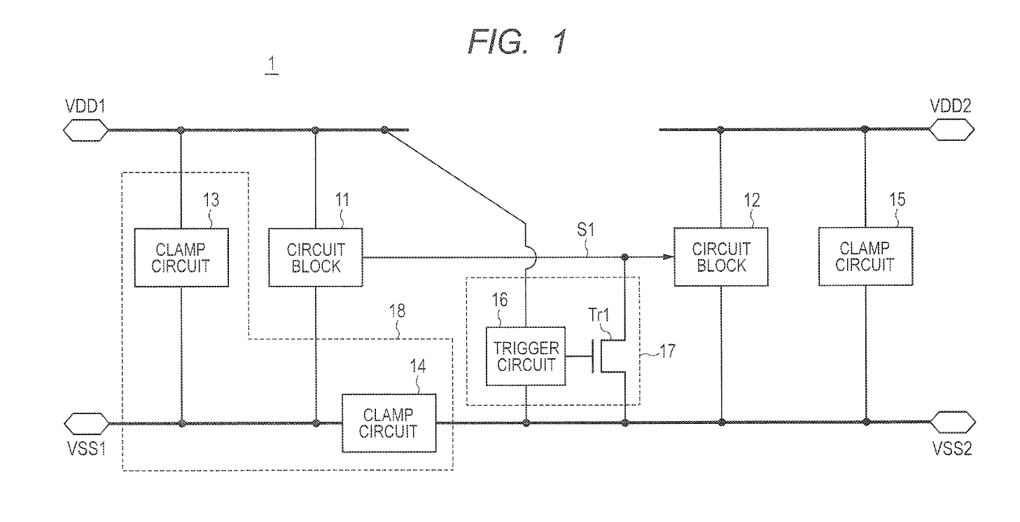

FIG. 1 is a block diagram illustrating a configuration example of a semiconductor integrated circuit 1 according to an embodiment 1. The semiconductor integrated circuit 1 according to this embodiment is capable of preventing gate breakdown of transistors which receive a signal transmitted between the circuit blocks driven by different power sources, even when electrostatic discharge of the CDM is generated, simply using a small-scale secondary clamp circuit. This will hereinafter be specifically described.

As illustrated in FIG. 1, the semiconductor integrated circuit 1 includes a circuit block 11, a circuit block 12, a clamp circuit 13, a clamp circuit 14, a clamp circuit 15, a trigger circuit 16, and a transistor Tr1. A clamp unit 18 is formed of the clamp circuits 13 and 14. For the primary clamp circuits 13 to 15, a secondary clamp 17 is formed of the trigger circuit 16 and the transistor Tr1.

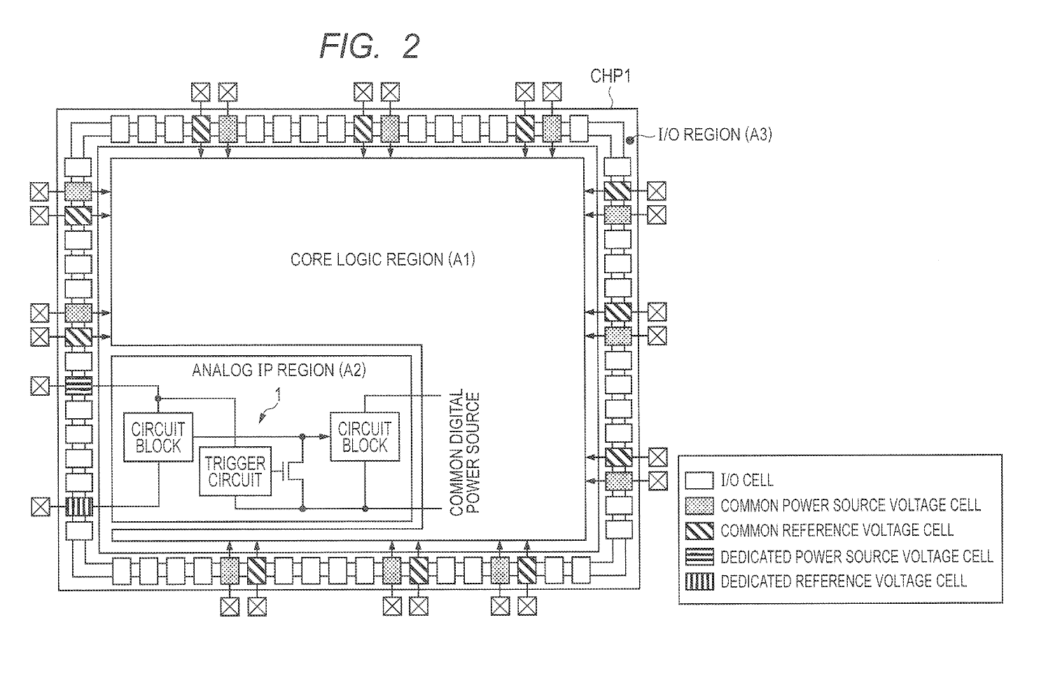

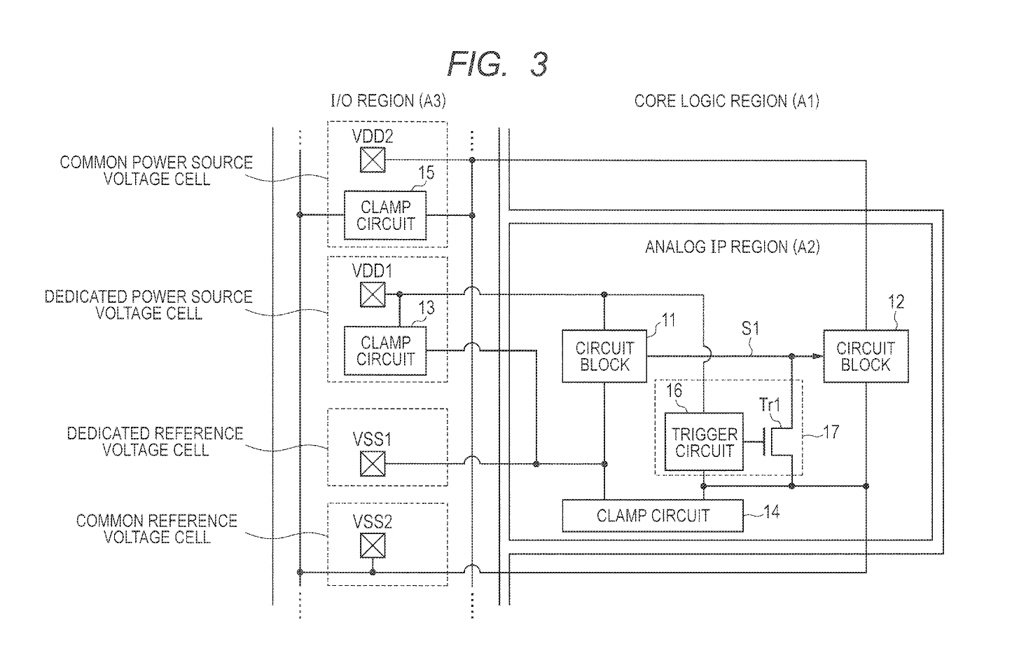

For example, the semiconductor integrated circuit 1 is provided in a small-scale analog IP (Intellectual Property) region, of a core logic region and the analog IP region which are separately formed over the semiconductor chip. Descriptions will now be made to an example of a layout configuration of the semiconductor device on which the semiconductor integrated circuit 1 is mounted, with reference to FIG. 2 and FIG. 3.

### (Example of Layout Configuration)

FIG. 2 is a diagram illustrating an example of a layout configuration of the semiconductor device on which the semiconductor integrated circuit 1 is mounted.

As seen from FIG. 2, there are provided internal circuit regions and an I/O region A3 which is provided to surround the periphery of them, over a semiconductor chip CHP1 of the semiconductor device. The internal circuit regions are formed of the core logic region A1 as a large-scale circuit region and the analog IP region A2 as a small-scale circuit region.

In the I/O region A3, there are arranged a plurality of I/O cells transmitting/receiving signals, a dedicated power source voltage cell and a dedicated reference voltage cell to which a dedicated power source voltage VDD1 and reference voltage VSS1 for driving the analog IP are supplied, and a plurality of common power source voltage cells and common reference voltage cells to which a common power source voltage VDD2 and a reference voltage VSS2 for driving the analog IP and the core logic are supplied.

FIG. 3 is a diagram illustrating an enlarged view of the periphery of the analog IP region A2, of the layout configuration of the semiconductor device illustrated in FIG. 2.

As illustrated in FIG. 3, the semiconductor integrated circuit 1 is mounted on the analog IP region A2. In the example of FIG. 3, of the constituent elements of the semiconductor integrated circuit 1, the clamp circuit 13 is provided in the dedicated power source voltage cell, while the clamp circuit 15 is provided in the common power source voltage cell. However, the clamp circuits 13 and 15 may be provided in the analog IP region A2. In the analog IP region A2, the secondary clamp circuit 17 is provided in the vicinity of a different power source crossing signal line S1.

The power source voltage VDD1 and the reference voltage VSS1, dedicated to the analog IP, are supplied directly to the analog IP region A2 externally via the dedicated power source voltage cell and the dedicated reference voltage cell. On the other hand, the common power source voltage VDD2 and the reference voltage VSS2 are supplied to the analog IP region A2 through the core logic region A1.

Descriptions will now be continued, referring back to FIG. 1.

The circuit block 11 is driven by the power source voltage VDD1 and the reference voltage VSS1, dedicated to the analog IP. The circuit bock 12 is driven by the power source voltage VDD2 and the reference voltage VSS2, common to the core logic. In this case, a signal is transmitted/received between the circuit blocks 11 and 12 driven by different power sources. In the example of FIG. 1, the circuit block 12 receives a signal S1 transmitted by the circuit block 11. A signal line to which the signal S1 is transmitted is referred to as a different power source crossing signal line S1.

Signal lines to which the power source voltages VDD1 and VDD2 are supplied will hereinafter be referred to as power source voltage lines VDD1 and VDD2, while lines to which the reference voltages VSS1 and VSS2 are supplied will hereinafter be referred to as reference voltage lines VSS1 and VSS2.

The clamp circuit 13 is provided between the power source voltage line VDD1 and the reference voltage line VSS1, and is conductive when it is detected that an ESD voltage (a surge voltage due to electrostatic discharge) is applied between the power source voltage line VDD1 and the reference voltage line VSS1.

For the clamp circuit 13, there is used an RC circuit with a relatively large time constant (a first time constant) of approximately several hundred nanoseconds to several microseconds, to detect not only electrostatic discharge of the CDM which represents a steep current rise in the unit of several hundred picoseconds and clamp the voltage, but also electrostatic discharge of the HBM and MM which represents a gentle current rise in the unit of several nanoseconds and clamp the voltage. Then, the clamp circuit 13 is capable of preventing electrostatic breakdown of the circuit block 11.

The clamp circuit 15 is provided between the power source voltage line VDD2 and the reference voltage line VSS2, and is conductive when it is detected that an ESD voltage is applied between the power source voltage line VDD2 and the reference voltage line VSS2.

In this case, the clamp circuit 15 uses an RC circuit with a relatively large time constant (a first time constant) of approximately several hundred nanoseconds to several microseconds, to detect not only electrostatic discharge of the CDM which represents a steep current rise in the unit of several hundred picoseconds and clamp the voltage, but also electrostatic discharge of the HBM and MM which represents a gentle current rise in the unit of several nanoseconds and clamp the voltage level. Then, the clamp circuit 15 is capable of preventing electrostatic breakdown of the circuit block 12.

The clamp circuit 14 is provided between the reference voltage line VSS1 and the reference voltage line VSS2, and clamps the voltage when a potential difference between the reference voltage lines VSS1 and VSS2 is equal to or greater than a predetermined value. In this case, the predetermined value is, for example, a forward drop voltage (approximately 0.7V) of the diode. Thus, for example, even when a large potential difference is generated between the power source voltage line VDD1 and the reference voltage line VSS2 due to generation of electrostatic discharge, the clamp circuits 13 and 14 operate, thereby reducing the gate voltage of a transistor (hereinafter also referred to as a transistor receiving a different power source crossing signal) in the circuit block 12 which receives a signal transmitted from the circuit block 11. This enables to prevent gate breakdown of the transistor which receives the different power source crossing signal.

In this embodiment, descriptions will now be made to a case in which a large current flows from the power source voltage line VDD1 to the reference voltage VSS2, when electrostatic discharge of the CDM is generated. This phenomenon can be realized by performing a CDM minus application test. In this CDM minus application test, after minus charges are accumulated in a parasitic capacitance (a package capacitance) formed between a semiconductor device on which the semiconductor integrated circuit 1 is mounted and a CDM tester, a probe at the ground level is made in contact with a test end (an end of a power source voltage VDD1), and a discharge current flowing through the probe is monitored at this time. In this case, the main part of the parasitic capacitance formed in the semiconductor device is formed on the side of the large-scale circuit region. At this time, a minus high voltage is applied to the reference voltage line VSS2 shared with the large-scale circuit region. Thus, when the probe at the ground level is made in contact with the power source voltage line VDD1, a large current flows from the power source voltage line VDD1 to the reference voltage line VSS2.

In recent years, with the subdivision of the process, the gate withstand voltage of the transistor receiving the different power source crossing signal is reduced. Thus, if a high ESD voltage is applied between the power source voltage line VDD1 and the reference voltage line VSS2 due to generation of the electrostatic discharge of the CDM, there is a possibility of breaking down the gate of the transistor which receives the different power source crossing signal S1. To solve this problem, if the performance of the clamp circuits 13 to 15 is simply improved, the size of the clamp circuits 13 to 15 gets increased, and the circuit scale of the semiconductor integrated circuit 1 is increased as well. In the semiconductor integrated circuit 1, the gate breakdown due to the electrostatic discharge of the CDM is prevented, without increasing the circuit scale, using the small-scale secondary clamp circuit 17 formed of the trigger circuit 16 and the transistor Tr1.

The trigger circuit 16 is provided between the power source voltage line VDD1 and the reference voltage line VSS2. When it is detected that an ESD voltage is applied between the lines VDD1 and VSS2 using a time constant (a second time constant) smaller than the time constant (the first time constant) of the clamp circuit 13, the trigger signal Strg is made active (for example, H level).

The transistor Tr1 is provided between the different power source crossing signal S1 and the reference voltage line VSS2, and is ON/OFF in accordance with the trigger signal Strg. For example, the transistor Tr1 is OFF, when the trigger signal Strg is inactive, and it is ON, when the trigger signal Strg is active. In this embodiment, descriptions are made to an example in which the transistor Tr1 is an N-channel MOS transistor. However, it is not limited to this example, and the transistor may be a P-channel MOS transistor.

As described above, the clamp circuits 13 and 15 need to perform clamping, not only upon the generation of the electrostatic discharge of the CDM which represents a steep current rise, but also upon the generation of the electrostatic discharge of the HBM and MM which represents a gentle current rise. Thus, the time constant of the clamp circuits 13 and 15 is adjusted to be a relatively large value of approximately several hundred nanoseconds to several microseconds.

On the other hand, the secondary clamp circuit 17 needs to perform clamping only upon the generation of the electrostatic discharge of the CDM which represents a steep current rise, and does not perform clamping upon the generation of the electrostatic discharge of the HBM and MM which represents a gentle current rise. Thus, the time constant of the trigger circuit 16 is adjusted to be a value (approximately, several dozen nanoseconds) smaller than the time constant of the clamp circuit 13.

For example, when the potential difference between the power source voltage line VDD1 and the reference voltage line VSS2 suddenly rises due to the generation of the electrostatic discharge of the CDM, the transistor Tr1 is ON. Then, the voltage applied to the gate of the transistor receiving the different power source crossing signal S1 is divided and reduced. As a result, it is possible to prevent the gate breakdown of the transistor which receives the different power source crossing signal S1.

On the other hand, when the potential difference between the power source voltage line VDD1 and the reference voltage line VSS2 gently rises due to the generation of the electrostatic discharge of the HBM and MM, the transistor Tr1 is kept OFF. However, by a clamp operation of the clamp circuits 13 to 15, the gate voltage of the transistor receiving the different power source crossing signal S1 is sufficiently reduced. As a result, it is possible to prevent the gate breakdown of the transistor receiving the different power source crossing signal S1. At this time, because the transistor Tr1 is kept OFF, it is possible to prevent over-current breakdown of the transistor Tr1 itself due to the electrostatic discharge of the HBM and MM having a large amount of heat.

The time constant of the trigger circuit 16 may be set to a small value for enabling to detect the electrostatic discharge of the CDM which represents a steep current rise. For example, the time constant of the clamp circuit 13 is set to several hundred nanoseconds to several microseconds, while the time constant of the trigger circuit 16 is set to several dozen nanoseconds. Thus, it is possible to downsize the resistance element and the capacitance element provided in the trigger circuit 16. For example, the resistance element is one having several k-Ω to several dozen k-Ω, while the capacitance element is one having several pF.

The transistor Tr1 is ON, only when the electrostatic discharge of the CDM is generated. Thus, it may simply have such a low withstand voltage that can withstand a small amount of heat generated by the electrostatic discharge of the CDM. It is, therefore, necessary to downsize the transistor Tr1. For example, the transistor Tr1 is one having a gate width of several μm to dozen μm.

That is, the semiconductor integrated circuit 1 uses the small-scale secondary clamp circuit 17 which is formed of the trigger circuit 16 and the transistor Tr1, thereby enabling to prevent the gate breakdown of the transistor receiving the different power source crossing signal, even when the electrostatic discharge of the CDM is generated.

### (Details of ESD Protective Operation at Generation of Electrostatic Discharge of CDM)

Subsequently, descriptions will specifically be made to an ESD protective operation by the semiconductor integrated circuit 1 at generation of electrostatic discharge of the CDM.

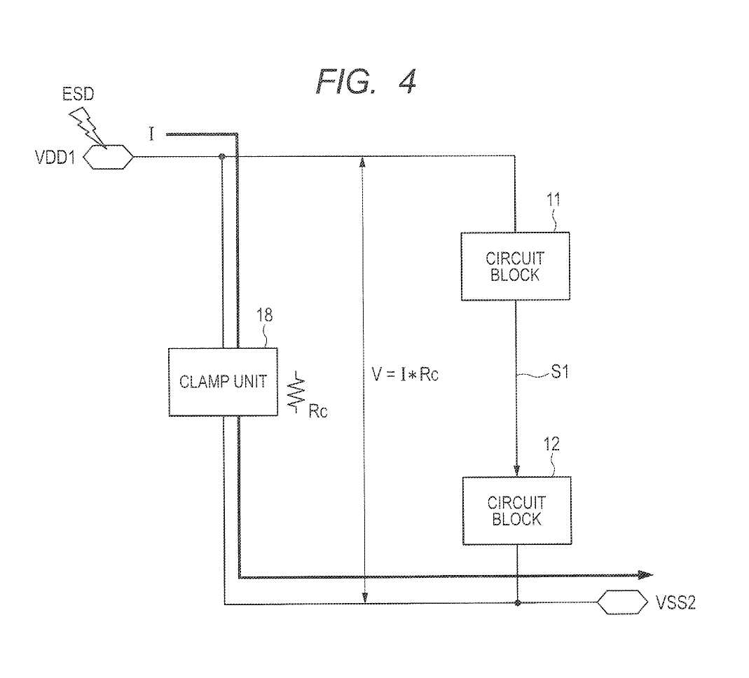

Descriptions will now be made to the ESD protective operation performed by the semiconductor integrated circuit before the secondary clamp circuit 17 is adopted. FIG. 4 is a diagram for explaining the ESD protective operation by the semiconductor integrated circuit before the secondary clamp circuit 17 is adopted.

As illustrated in FIG. 4, in a configuration without the secondary clamp circuit 17, an ESD current I flows from the power source voltage line VDD1 to the reference voltage line VSS2 via the clamp unit 18, at generation of electrostatic discharge of the CDM. In this case, if the impedance of the clamp unit 18 is represented as Rc, the potential difference (ESD voltage) Vcdm between the VDD1 and VSS2 is represented as I*Rc. This high ESD voltage Vcdm is applied as is to the gate of the transistor in the circuit block 12 receiving the signal S1 transmitted from the circuit block 11. This may cause the gate breakdown of the transistor.

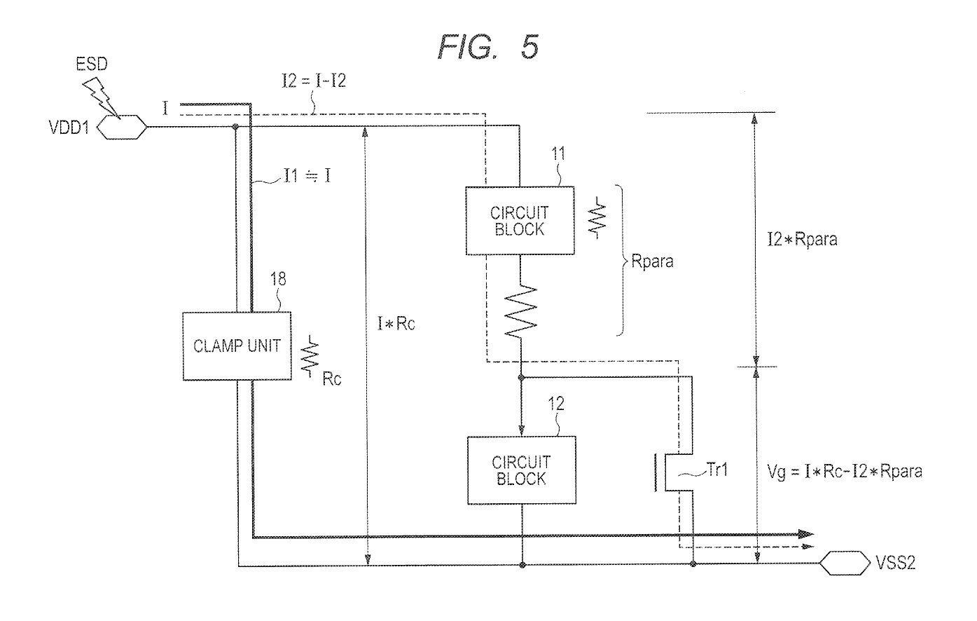

Descriptions will now be made to the ESD protective operation performed by the semiconductor integrated circuit 1 in which the secondary clamp circuit 17 is adopted. FIG. 5 is a diagram for explaining the ESD protective operation by the semiconductor integrated circuit 1 in which the secondary clamp circuit 17 is adopted.

As illustrated in FIG. 5, in the configuration with the secondary clamp circuit 17 provided therein, when the electrostatic discharge of the CDM has been generated, the ESD current I is spread into two current paths and flows. Specifically, a current I1 of the ESD current I flows from the power source voltage line VDD1 to the reference voltage line VSS2 via the clamp unit 18, while a rest current I2 flows from the power source voltage line VDD1 to the reference voltage line VSS2 via the different power source crossing signal S1 and the transistor Tr1.

In this case, the impedance Rc of the current path via the clamp unit 18 is low, for example, equal to or lower than 1Ω, while the impedance Rpara of the current path via the different power source crossing signal S1 is high, for example, approximately several hundred Ω, because it includes wiring resistance of the different power source crossing signal S1. Thus, the main part of the ESD current I flows through the current path via the clamp unit 18. The potential difference (ESD voltage) Vcdm between the VDD1 and VSS2 is obtained by I1*Rc≈I*Rc. The gate voltage Vg of the transistor receiving the different power source crossing signal represents a lower value than the ESD voltage Vcdm by an amount of the voltage drop at the impedance Rpara. Specifically, the gate voltage Vg=I+Rc−I2*Rpara.

As described above, in the configuration without the secondary clamp circuit 17, the gate voltage Vg of the transistor receiving the different power source crossing signal S1 is obtained by I*Rc. In the configuration with the secondary clamp circuit 17 provided therein, the gate voltage Vg of the transistor receiving the different power source crossing signal S1 is lower by an amount corresponding to I2*Rpara. Then, the semiconductor integrated circuit 1 is capable of preventing the gate breakdown of the transistor receiving the different power source crossing signal S1, even at the generation of the electrostatic discharge of the CDM.

As described above, the semiconductor integrated circuit 1 according to this embodiment is capable of preventing the gate breakdown of the transistor receiving the signal transmitted between the circuit blocks driven by different power sources, even at the generation of the electrostatic discharge of the CDM.

The specific configuration of each block provided in the semiconductor integrated circuit 1 is not particularly limited, as long as it has the above functions. Descriptions will hereinafter briefly be made to the specific configuration of each block.

### (Specific Configuration Example of Each Block)

Descriptions will now be made to a specific configuration example of the clamp circuits 13 to 15 and the trigger circuit 16.

### (Configuration Example of Clamp Circuit 13)

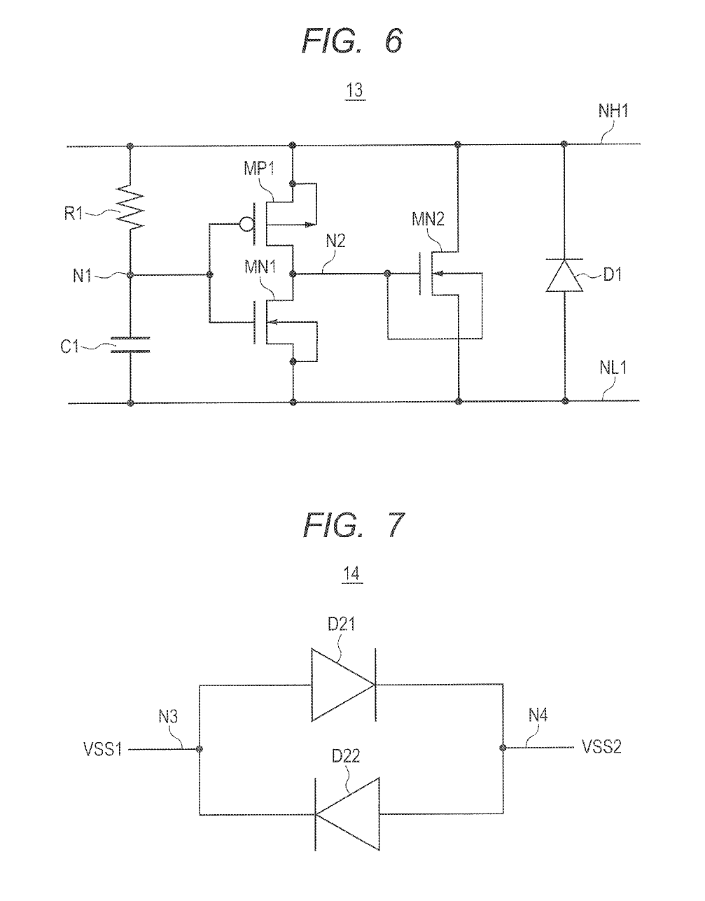

FIG. 6 is a diagram illustrating a specific configuration example of the clamp circuit 13.

As illustrated in FIG. 6, the clamp circuit 13 has a resistance element R1, a capacitance element C1, transistors MP1, MN1, and MN2, and a diode D1. Descriptions will be made to a case in which the transistor MP1 is a P-channel MOS transistor, while the transistors MN1 and MN2 are N-channel MOS transistors, by way of example, in FIG. 6.

A high potential side power source terminal NH1 of the clamp circuit 13 is coupled to the power source voltage line VDD1, while a low potential side power source terminal NL1 of the clamp circuit 13 is coupled to the reference voltage line VSS1.

The resistance element R1 and the capacitance element C1 are provided in series between the high potential side power source terminal NH1 and the low potential side power source terminal NL1. In this case, the resistance element R1 and the capacitance element C1 are provided to form an RC circuit of the clamp circuit 13.

In the transistor MP1, the source is coupled to the high potential side power source terminal NH1, the drain is coupled to a node N2, and the gate is coupled to a node N1 between the resistance element R1 and the capacitance element C1. In the transistor MN1, the source is coupled to the low potential side power source terminal NL1, the drain is coupled to the node N2, and the gate is coupled to the node N1. In this case, the transistors MP1 and MN1 form an inverter, and output a potential of the node N2 which has been obtained by logically inverting the potential of the node N1.

In the transistor MN2, the source is coupled to the low potential side power source terminal NL1, the drain is coupled to the high potential side power source terminal NH1, and the gate and the back gate are coupled to the node N2. In the diode D1, the anode is coupled to the low potential side power source terminal NL1, and the cathode is coupled to the high potential side power source terminal NH1.

In this case, the clamp circuit 13 needs to detect generation of not only the electrostatic discharge of the CDM which represents a steep current rise in the unit of several hundred picoseconds and clamp the voltage level, but also the electrostatic discharge of the HBM and MM which represents a gentle current rise in the unit of several nanoseconds and clamp the voltage. Thus, for the clamp circuit 13, there is used an RC circuit with a relatively large time constant (a first time constant) of approximately several hundred nanoseconds to several microseconds. That is, for the clamp circuit 13, the resistance element R1 with a large resistance value and a capacitance element C1 with a large capacitance value are used.

For example, when the potential of the high potential side power source terminal NH1 gets higher than the potential of the low potential side power source terminal NL1 due to the generation of the electrostatic discharge, the potential of the node N1 gradually increases, in accordance with the time constant determined by the resistance element R1 and the capacitance element C1. When the potential of the node N1 is lower than a threshold voltage of the inverter which is formed of the transistors MP1 and MN1, the node N2 outputs a signal with the H level. Then, the transistor MN2 is turned ON. As a result, an electrostatic discharge current applied to the high potential side power source terminal NH1 flows to the low potential side power source terminal NL1 via the clamp circuit 13. That is, clamping is performed for the high ESD voltage between the power source voltage line VDD1 and the reference voltage line VSS1. As a result, the clamp circuit 13 is capable of preventing withstand voltage breakdown of each transistor provided in the circuit block 11.

When the potential of the low potential side power source terminal NL1 gets lower than the potential of the high potential side power source terminal NH1 due to the generation of the electrostatic discharge, a current flows from the low potential side power source terminal NL1 to the high potential side power source terminal NH1 via the diode D1. As a result, the clamp circuit 13 is capable of preventing withstand voltage breakdown of each transistor provided in the circuit block 11.

The configuration of the clamp circuit 13 is not limited to that illustrated in FIG. 6. It may be appropriately changed to any other configuration having the same functions.

### (Configuration Example of Clamp Circuit 15).

The configuration of the clamp circuit 15 is the same as that of the clamp circuit 13, and thus will not be described over and over. Note, however, that the high potential side power source terminal NH1 of the clamp circuit 15 is coupled to the power source voltage line VDD2, and the low potential side power source terminal NL1 of the clamp circuit 15 is coupled to the reference voltage line VSS2.

### (Configuration Example of Clamp Circuit 14)

FIG. 7 is a diagram illustrating a specific configuration example of the clamp circuit 14.

As illustrated in FIG. 7, the clamp circuit 14 has diodes D21 and D22 which are coupled in parallel in opposite directions to each other. In more particularly, the anode of the diode D21 and the cathode of the diode D22 are coupled to a node N3, and the cathode of the diode D21 and the anode of the diode D22 are coupled to a node N4. The opposite length between the diodes D21 and D22 is approximately several dozen μm to hundred and several dozen μm.

The node N3 of the clamp circuit 14 is coupled to the reference voltage line VSS1, and the node N4 of the clamp circuit 14 is coupled to the reference voltage line VSS2.

At the generation of a potential difference equal to or greater than the forward drop voltage Vf (approximately 0.7V) of the diodes D21 and D22 between the reference voltage lines VSS1 and VSS2, the clamp circuit 14 clamps the voltage to a forward drop voltage Vf or below. When the potential difference between the reference voltage lines VSS1 and VSS2 is lower than the forward drop voltage Vf of the diodes D21 and D22, the clamp circuit 14 does not perform clamping. As a result, it is possible to prevent propagation of the noise generated in one of the reference voltage lines VSS1 and VSS2.

The configuration of the clamp circuit 14 is not limited to the configuration of FIG. 7. It may appropriately be changed to any other configuration having the same functions.

### (First Specific Configuration Example of Trigger Circuit 16)

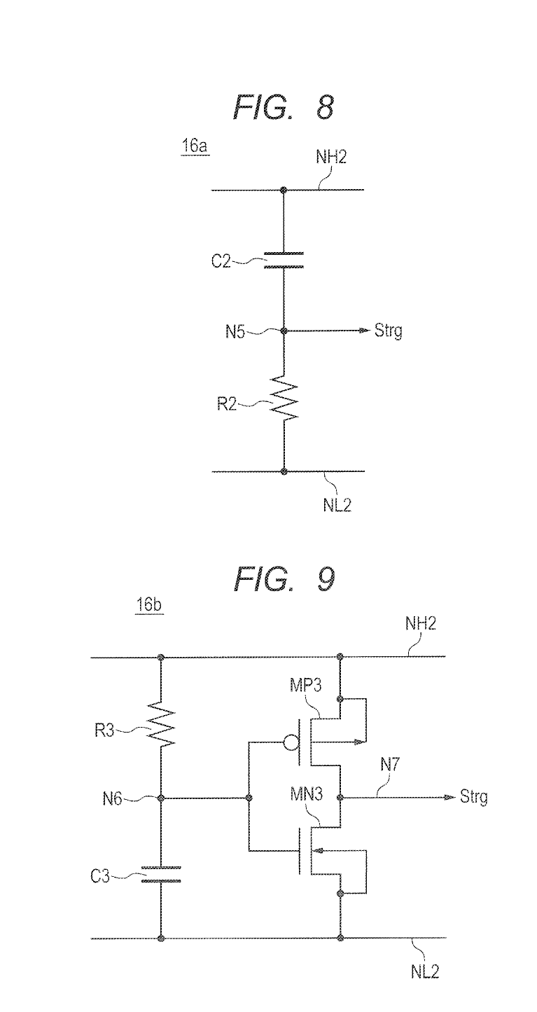

FIG. 8 is a diagram illustrating a first specific configuration example of the trigger circuit 16, as a trigger circuit 16a.

As illustrated in FIG. 8, the trigger circuit 16a has a capacitance element C2 and a resistance element R2. The capacitance element C2 and the resistance element R2 are provided in series between a high potential side power source terminal NH2 and a low potential side power source terminal NL2. The potential of a node N5 between the capacitance element C2 and the resistance element R2 is output as a trigger signal Strg.

The high potential side power source terminal NH2 of the trigger circuit 16a is coupled to the power source voltage line VDD1, and the low potential side power source terminal NL2 of the trigger circuit 16a is coupled to the reference voltage line VSS2.

Only at the generation of the electrostatic discharge of the CDM which represents a steep current rise, the trigger circuit 16 needs to perform clamping. At the generation of the electrostatic discharge of the HBM and MM which represents a gentle current rise, the circuit does not perform clamping. For the trigger circuit 16, the resistance element R2 with a small resistance value and the capacitance element C2 with a small capacitance value are used, to obtain a time constant with a value (approximately, several dozen nanoseconds) smaller than the time constant of the clamp circuit 13. For example, the resistance element R2 is one having several k-Ω to several dozen of k-Ω, and capacitance element C2 is one having several pF.

At the generation of the electrostatic discharge, a displacement current i flows from the high potential side power source terminal NH2 to the low potential side power source terminal NL2, upon a potential rise of the power source voltage line VDD1. In this case, the potential (the potential of the node N5) of the trigger signal Strg is represented by a product (a drop voltage at the resistance element R2) of the displacement current i and the resistance element R2. The displacement current i is represented by a product of the capacitance value of the capacitance element C2 and the voltage rising velocity dV/dt between the VDD1 and VSS2.

For example, at the generation of the electrostatic discharge of the CDM which represents a steep current rise, the value of the voltage change velocity dV/dt increases. Even if the capacitance value C2 is small, a displacement current i is large. Thus, the trigger signal Strg can rise up to a potential sufficiently enough for the transistor Tr1 to be turned ON. That is, at the generation of the electrostatic discharge of the CDM, the secondary clamp circuit performs a clamping operation. On the contrary, at the generation of the electrostatic discharge of the HBM and MM which represents a gentle current rise, the value of the voltage change velocity dV/dt is small. Thus, the displacement current i is small. Thus, the trigger signal Strg does not rise to a potential sufficiently enough for the transistor Tr1 to be turned ON. That is, at the generation of the electrostatic discharge of the HBM and MM, the secondary clamp circuit does not perform the clamping operation.

### (Second Specific Configuration Example of Trigger Circuit 16)

FIG. 9 is a diagram illustrating a second specific configuration example of the trigger circuit 16 as a trigger circuit 16b.

As illustrated in FIG. 9, the trigger circuit 16b has a resistance element R3, a capacitance element C3, and transistors MP3 and MN3. Descriptions will now be made to a case in which the transistor MP3 is a P-channel MOS transistor, and the transistor MN3 is an N-channel MOS transistor, by way of example in FIG. 9.

The high potential side power source terminal NH2 of the trigger circuit 16b is coupled to the power source voltage line VDD1, while the low potential side power source terminal NL2 of the trigger circuit 16b is coupled to the reference voltage line VSS2.

The resistance element R3 and the capacitance element C3 are provided in series between the high potential side power source terminal NH2 and the low potential side power source terminal NL2. In the transistor MP3, the source is coupled to the high potential side power source terminal NH2, the drain is coupled to a node N7, and the gate is coupled to a node N6 between the resistance element R3 and the capacitance element C3. In the transistor MN3, the source is coupled to the low potential side power source terminal NL2, the drain is coupled to the node N7, and the gate is coupled to the node N6. The transistors MP3 and MN3 are provided to form an inverter, and output a potential of the node N7 as a trigger signal Strg. This potential of the node N7 has been obtained by logically inverting the potential of the node N6.

The configuration of the trigger circuit 16 is not limited to the configuration of FIG. 8 and FIG. 9, and can appropriately be changed to any other configuration having the same functions.

### (Modification of Semiconductor Integrated Circuit 1)

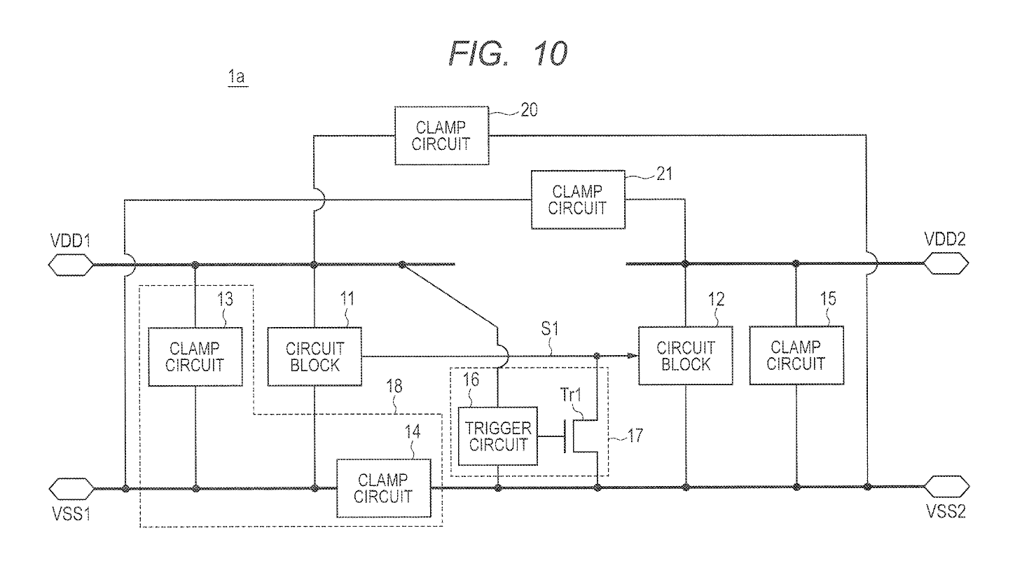

Descriptions will now be made to a modification of the semiconductor integrated circuit 1 using FIG. 1. FIG. 10 is a block diagram illustrating the modification of the semiconductor integrated circuit 1 as a semiconductor integrated circuit 1a. The semiconductor integrated circuit 1a includes clamp circuits 20 and 21, unlike the configuration of the semiconductor integrated circuit 1.

The clamp circuit 20 has the same circuit configuration as that of the clamp circuits 13, and is provided between the power source voltage line VDD1 and the reference voltage line VSS2. The clamp circuit 21 has the same circuit configuration as that of the clamp circuit 13, and is provided between the power source voltage line VDD2 and the reference voltage line VSS1.

Other configurations of the semiconductor integrated circuit 1a are the same as those of the semiconductor integrated circuit 1, and thus will not be described over and over.

The semiconductor integrated circuit 1a includes the clamp circuits 20 and 21. This enables to reduce the rate of a current flowing through the difference power source crossing signal line S1, at the generation of the electrostatic discharge of the CDM. Then, the gate voltage of the transistor receiving the different power source crossing signal S1 is further decreased. That is, the semiconductor integrated circuit 1a is capable of preventing gate breakdown of the transistor receiving the different power source crossing signal S1, even when the gate withstand voltage of the transistor is further reduced with further subdivision of the process.

### Embodiment 2

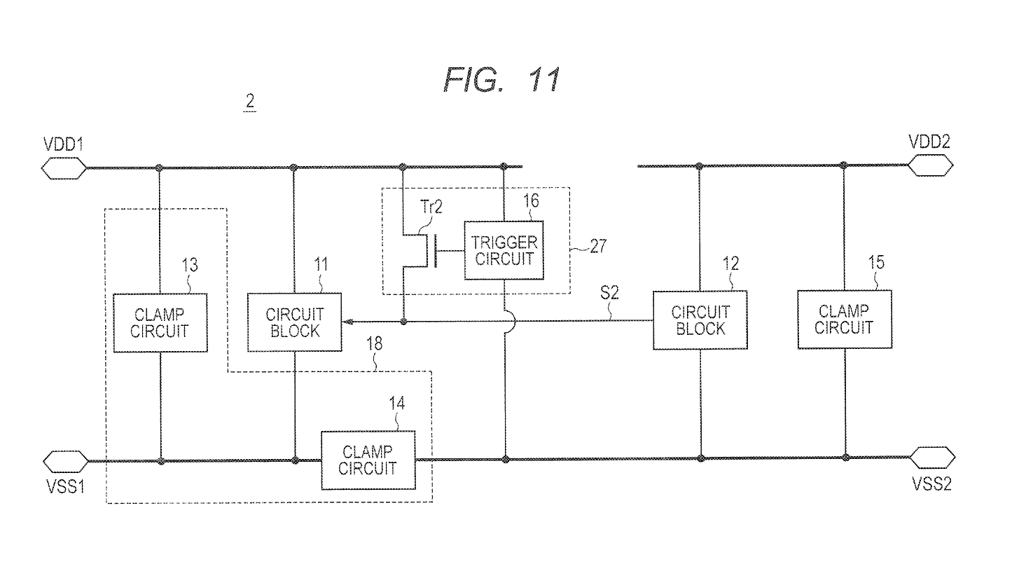

FIG. 11 is a block diagram illustrating a configuration example of a semiconductor integrated circuit 2 according to an embodiment 2. The semiconductor integrated circuit 1 has the configuration for protecting the transistor, in the circuit block 12 which receives the different power source crossing signal S1, from ESD breakdown. The semiconductor integrated circuit 2 has a configuration for protecting the transistor, in the circuit block 11 receiving a different power source crossing signal S2, from ESD breakdown. Descriptions will hereinafter be made thereto.

The semiconductor integrated circuit 2 includes a secondary clamp circuit 27, in place of the secondary clamp circuit 17 of the semiconductor integrated circuit 1. The secondary clamp circuit 27 has a transistor Tr2 and a trigger circuit 16. The transistor Tr2 is provided between the different power source crossing signal line S2 and the power source voltage line VDD1, and is ON/OFF in accordance with a trigger signal Strg from the trigger circuit 16. In this embodiment, descriptions will now be made to a case in which the transistor Tr2 is an N-channel MOS transistor. However, the transistor is not limited to this, and may be a P-channel MOS transistor.

Other configurations of the semiconductor integrated circuit 2 are the same as those of the semiconductor integrated circuit 1, and thus will not be described over and over.

At the generation of electronic discharge of the CDM, a gate voltage Vg of the transistor in the circuit block 11 receiving the different power source signal S2 is lower than an ESD voltage Vcdm by an amount of a voltage drop at the wiring resistance of the different power source crossing signal S2. Then, the semiconductor integrated circuit 2 is capable of preventing gate breakdown of the transistor receiving the different power source crossing signal S2, even at the generation of the electrostatic discharge of the CDM.

### (Modification of Semiconductor Integrated Circuit 2)

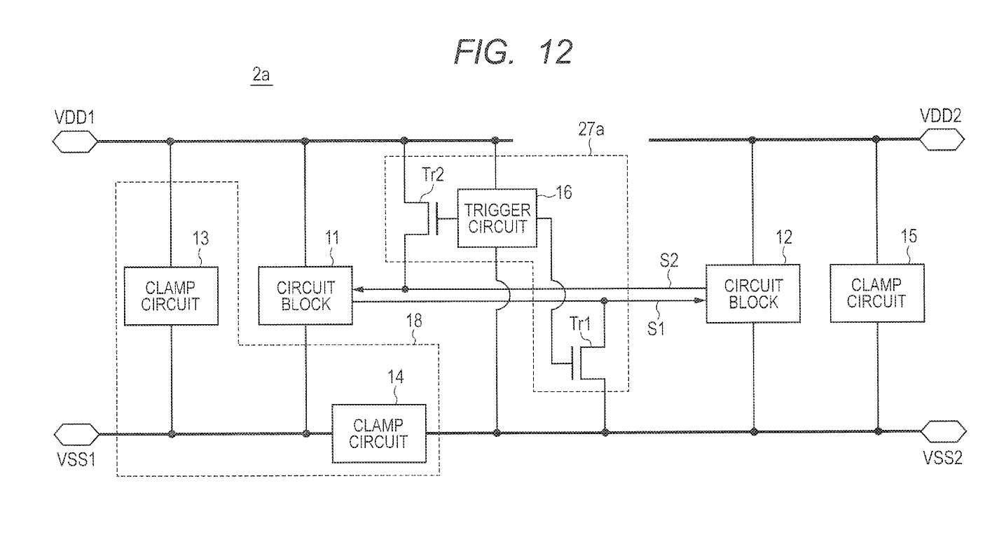

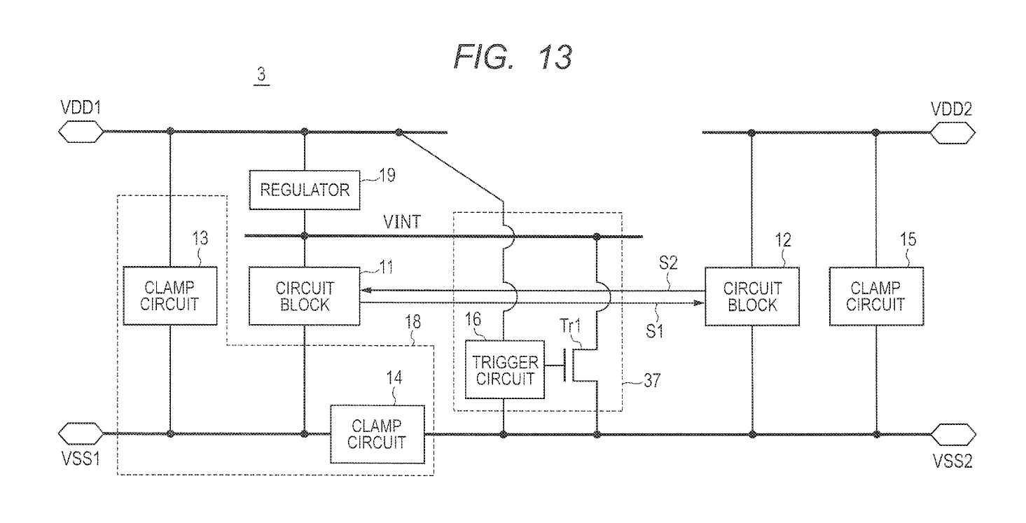

FIG. 12 is a block diagram illustrating a modification of the semiconductor integrated circuit 2 as a semiconductor integrated circuit 2a. The semiconductor integrated circuit 2a is a combination of the semiconductor integrated circuit 2 and the semiconductor integrated circuit 1. Descriptions will hereinafter be made thereto.

The semiconductor integrated circuit 2a includes a secondary clamp circuit 27a, in place of the secondary clamp circuit 27 of the semiconductor integrated circuit 2. The secondary clamp circuit 27a has the transistors Tr1 and Tr2, and the trigger circuit 16. The transistor Tr1 is provided between the different power source crossing signal line S1 and the reference voltage line VSS2, and is ON/OFF in accordance with the trigger signal Strg. The transistor Tr2 is provided between the different power source crossing signal line S2 and the power source voltage line VDD1, and is ON/OFF in accordance with the trigger signal Strg.

Other configurations of the semiconductor integrated circuit 2a are the same as those of the semiconductor integrated circuit 2, and thus will not be described over and over.

Like the semiconductor integrated circuits 1 and 2, the semiconductor integrated circuit 2a is capable of preventing gate breakdown of the transistors receiving the different power source crossing signals S1 and S2, even at the generation of the electrostatic discharge of the CDM.

### Embodiment 3

FIG. 13 is a block diagram illustrating a configuration example of a semiconductor integrated circuit 3 according to an embodiment 3. The semiconductor integrated circuit 3 further includes a regulator 19, unlike the semiconductor integrated circuit 1. It also includes a secondary clamp circuit 37 in place of the secondary clamp circuit 17.

The regulator 19 generates a predetermined stable internal voltage VINT from the power source voltage VDD1. A line to which the internal voltage VINT is supplied will hereinafter be referred to as an internal voltage line VINT. In this case, the circuit block 11 is provided between the internal voltage line VINT and the reference voltage line VSS1. That is, the circuit block 11 is driven by the internal voltage VINT and the reference voltage VSS1.

The secondary clamp circuit 37 has the transistor Tr1 and the trigger circuit 16. The trigger circuit 16 is provided between the power source voltage line VDD1 and the reference voltage line VSS1, and causes the trigger signal Strg to be active (for example, H level), when it is detected that an ESD voltage is applied between the VDD1 and VSS2 using a second time constant. The transistor Tr1 is provided between the internal voltage line VINT and the reference voltage line VSS2, and is ON/OFF in accordance with the trigger signal Strg.

The different power source crossing signal S1 is transmitted from the circuit block 11 to the circuit block 12, while the different power source crossing signal S2 from the circuit block 12 to the circuit block 11.

At the generation of the electrostatic discharge of the CDM, the gate voltage of the transistor in the circuit block 12 receiving the different power source crossing signal S1 and the gate voltage of the transistor in the circuit block 11 receiving the different power source crossing signal S2 are both lower than the ESD voltage Vcdm by an amount of a voltage drop in the regulator 19. As a result, the semiconductor integrated circuit 3 is capable of preventing gate breakdown of the transistor which receives the different power source crossing signals S1 and S2, even at the generation of the electrostatic discharge of the CDM.

The semiconductor integrated circuit 3 does not need to have a plurality of transistors Tr1 or Tr2 for a plurality of different power source crossing signal lines, even when a plurality of different power source crossing signals exist. Only one transistor Tr1 may be provided between the internal voltage line VINT and the reference voltage line VSS2. As a result, it is possible to form a simple circuit configuration, and it is also possible to suppress an increase in the circuit scale.

The clamp circuits 20 and 21 illustrated in FIG. 10 may additionally be provided in the configuration of the semiconductor integrated circuit 3. This causes to reduce the rate of the current flowing through the different power source crossing signal S1, at the generation of the electrostatic discharge of the CDM. This results in reducing the gate voltage of the transistor receiving the different power source crossing signal S1. That is, even when the gate withstand voltage of the transistor is further reduced due to the subdivision of the process, the semiconductor integrated circuit 3 is capable of preventing gate breakdown of the transistor receiving the different power source crossing signal S1.

Accordingly, the semiconductor integrated circuit according to the above-described embodiments 1 to 3 and the semiconductor device including any of them are capable of preventing the gate breakdown of the transistor receiving a signal transmitted between circuit blocks driven by different power sources, simply with using the small-scale secondary clamp circuit, even at the generation of the electrostatic discharge of the CDM. In this case, in the secondary clamp circuit, the trigger circuit may have a time constant with such a small value that enables to detect the electrostatic discharge of the CDM which represents a steep current rise, and also the transistor Tr1 (Tr2) may have such a small withstand voltage that can withstand a small amount of heat generated due to the electrostatic discharge of the CDM. Thus, the secondary clamp circuit can be configured with a small-scale trigger circuit and the transistor Tr1 (Tr2). Thus, there is almost no effect on an increase in the circuit scale of the semiconductor integrated circuit due to the addition of the secondary clamp circuit.

Accordingly, the descriptions have specifically been made to the inventions made by the present inventors based on the embodiments. However, the present invention is not limited to the above-described embodiments. Various changes may possibly be made without departing from the scope thereof.

For example, in the above-described embodiments, it is possible to invert the conductive type (p-type or n-type) of the semiconductor substrate, the semiconductor layer, and the diffusion layer (diffusion area). When one of the conductive types of the n-type and p-type is assumed as a first conductive type, and the other conductive type is assumed as a second conductive type, the first conductive type may be the p-type, while the second conductive type may be the n-type. On the contrary, the first conductive type may be the n-type, while the second conductive type may be the p-type.

What is claimed is:

1. A semiconductor integrated circuit comprising:
a first circuit block which is provided between a first power source voltage line and a first reference voltage line;
a second circuit block which is provided between a second power source voltage line and a second reference voltage line;
a clamp unit which is provided between the first power source voltage line and the second reference voltage line, and is conductive when it is detected that an ESD voltage is applied between the first power source voltage line and the second reference voltage line using a first time constant;
a trigger circuit which is provided between the first power source voltage line and the second reference voltage line, and causes a trigger signal to be active when it is detected that an ESD voltage is applied between the first power source voltage line and the second reference voltage line using a second time constant smaller than the first time constant; and
a switch which is provided between a signal line between the first and second circuit blocks and one of the first power source voltage line and the second reference voltage line, and is ON when the trigger signal is active.

2. The semiconductor integrated circuit according to claim 1,
wherein the switch is a MOS transistor.

3. The semiconductor integrated circuit according to claim 1,
wherein the clamp unit has
a first clamp circuit which is provided between the first power source voltage line and the first reference voltage line, and
a second clamp circuit which is provided between the first reference voltage line and the second reference voltage line.

4. The semiconductor integrated circuit according to claim 3, further comprising
a third clamp circuit which is provided between the first power source voltage line and the second reference voltage line.

5. The semiconductor integrated circuit according to claim 1,
wherein the signal line transmits a signal transmitted from the first circuit block to the second circuit block, and
wherein the switch is provided between the signal line and the second reference voltage line.

6. The semiconductor integrated circuit according to claim 1,
wherein the signal line transmits a signal transmitted from the second circuit block to the first circuit block, and
wherein the switch is provided between the signal line and the first power source voltage line.

7. The semiconductor integrated circuit according to claim 1,
wherein the signal line is a first signal line for transmitting a signal transmitted from the first circuit block to the second circuit block, and
wherein the switch is a first switch provided between the first signal line and the second reference voltage line, and includes
a second signal line for transmitting a signal from the second circuit block to the first circuit block, and
a second switch provided between the second signal line and the first power source voltage line.

8. A semiconductor device comprising:
a semiconductor chip;
an analog circuit which is provided over the semiconductor chip, and has the semiconductor integrated circuit according to claim 1; and
a core logic circuit which is provided over the semiconductor chip together with the analog circuit, and has a circuit scale larger than the analog circuit,
wherein a first power source voltage and a first reference voltage are supplied externally from the semiconductor chip respectively to the first power source voltage line and the first reference voltage line, and
a second power source voltage and a second reference voltage commonly used with the core logic circuit are supplied respectively to the second power source voltage line and the second reference voltage line.

9. A semiconductor integrated circuit comprising:
a regulator which generates a predetermined internal voltage from a first power source voltage supplied to a first power source voltage line;
a first circuit block which is provided between an internal voltage line to which the internal voltage is supplied and a first reference voltage line;
a second circuit block which is provided between a second power source voltage line and a second reference voltage line;
a clamp unit which is provided between the first power source voltage line and the second reference voltage line, and is conductive when it is detected that an ESD voltage is applied between the first power source voltage line and the second reference voltage line using a first time constant;
a trigger circuit which is provided between the first power source voltage line and the second reference voltage line, and causes a trigger signal to be active, when it is detected that an ESD voltage is applied between the first power source voltage line and the second reference voltage line using a second time constant smaller than the first time constant; and
a switch which is provided between the internal voltage line and the second reference voltage line, and is ON when the trigger signal is active.

10. The semiconductor integrated circuit according to claim 9,
wherein the switch is a MOS transistor.

11. The semiconductor integrated circuit according to claim 9,
wherein the clamp unit has
a first clamp unit which is provided between the first power source voltage line and the first reference voltage line, and
a second clamp unit which is provided between the first reference voltage line and the second reference voltage line.

12. The semiconductor integrated circuit according to claim 11, further comprising
a third clamp unit which is provided between the first power source voltage line and the second reference voltage line.

13. A semiconductor device comprising:
a semiconductor chip;
an analog circuit which is provided over the semiconductor chip and has the semiconductor integrated circuit according to claim 9; and
a core logic circuit which is provided over the semiconductor chip together with the analog circuit, and has a circuit scale larger than the analog circuit,
wherein a first power source voltage line and a first reference voltage are supplied externally from the semiconductor chip respectively to the first power source voltage line and the first reference voltage line, and
wherein a second power source voltage and a second reference voltage commonly shared with the core logic circuit are supplied respectively to the second power source voltage line and the second reference voltage line.
